(19) United States
(12) Patent Application Publication
(10) Pub. No.: US 2024/0422943 A1
(43) Pub. Date: Dec. 19, 2024

(54) SOLID-STATE THERMAL ENERGY STORAGE AND DISSIPATION

(71) Applicant: U.S. Army DEVCOM, Army Research Laboratory, Adelphi, MD (US)

(72) Inventors: Darin J. Sharar, Silver Spring, MD (US); Adam A. Wilson, Columbia, MD (US); Andrew J. Bayba, Sierra Vista, AZ (US); Asher C. Leff, Guaynabo, PR (US)

(21) Appl. No.: 18/370,911

(22) Filed: Sep. 21, 2023

Related U.S. Application Data
(60) Provisional application No. 63/521,035, filed on Jun. 14, 2023.

(51) Int. Cl. H05K 7/20

(52) U.S. Cl. CPC H05K 7/20336; H05K 7/2039; C09K 5/06

(57) ABSTRACT

Various novel heat exchange components which are designed and/or configured to effectively and efficiently dissipate thermal energy (heat) away from a heat source are described. The heat exchange component structures may be a composite formed of two or more distinct types of materials including a thermally conductive material and a solid state (SS) Martensitic transformation (MT) phase change material (PCM). The thermally conductive material may be configured so as to form or provide for: (i) a heat receiving section configured to be in contact with a heat source so as to receive thermal energy from the heat source, and (ii) a thermal energy spreading section configured to pull thermal energy away from the heat receiving section and distribute it into and/or throughout the entire the heat exchange structure, especially, into and/or through the SS MT PCM.

### CROSS-REFERENCE TO RELATED APPLICATIONS

This application claims priority to U.S. Provisional Patent Application Ser. No. 63/521,035, filed on Jun. 14, 2023. U.S. Patent Publication No. US2020/0407615A1, published Dec. 31, 2020, is incorporated by reference herein.

### GOVERNMENT INTEREST

The invention described herein may be manufactured, used and licensed by or for the U.S. Government.

### FIELD OF THE INVENTION

The invention relates to thermal energy storage and transient heat transfer.

### BACKGROUND OF THE INVENTION

Existing solutions have steady state cooling capability appropriate for continuous peak load, resulting in significant overdesign. Existing solutions that utilize phase changing materials (PCM) may include PCM materials that expand as temperature increases, causing packaging and/or voiding issues. Standard PCM solutions may only work over a narrow temperature range, requiring system redesign for different application spaces. PCMs such as paraffins have low specific gravity and low thermal conductivity, resulting in higher PCM volume for a given heat storage application and limited thermal transport.

Existing PCM solutions may suffer from a large degree of supercooling, whereby re-solidification occurs at a much lower temperature than the melt temperature, causing repeatability and efficiency issues. Many multi-constituent PCM materials (such as salt hydrates) do not melt congruently and settle over repeated phase change cycles, resulting in reduced performance. Many PCM materials, such as salt hydrates, are corrosive. Many PCM materials, such as lower melting temperature metals, include lead or cadmium, making the PCM materials non-compliant with various regulations. Many PCMs, such as solid-liquid metals, require complex packaging processes to incorporate and encapsulate the PCM into existing packages.

Thus, there is a need for a PCM-base thermal energy storage and transfer solution that is able to use standard packaging processes, operate over a wide temperature range, provide adequate thermal conductivity, with repeatable and efficient performance.

### BRIEF SUMMARY OF THE INVENTION

Some embodiments may provide solid-state thermal energy storage and dissipation. A solid-state thermal energy storage and dissipation device or component of some embodiments may include a thermal conductor and a solid-state (SS) martensitic transformation (MT) PCM thermal storage element.

The thermal conductor may receive heat from a heat source and dissipate the heat to the SS MT PCM thermal storage element. The thermal conductor may include a set of dendrites that extend away from the heat source.

### BRIEF DESCRIPTION OF THE DRAWINGS

The novel features of the disclosure are set forth in the appended claims. However, for purpose of explanation, several embodiments are illustrated in the following drawings.

FIG. 1 illustrates an example solid-state thermal energy storage and dissipation element of one or more embodiments described herein;

FIG. 2 illustrates an example solid-state thermal energy storage and dissipation element with cooling ports of one or more embodiments described herein;

FIG. 3A illustrates a top plan view of an example solid-state thermal energy storage and dissipation element of one or more embodiments described herein;

FIG. 3B illustrates a top plan view of an example solid-state thermal energy storage and dissipation element of one or more embodiments described herein;

FIG. 3C illustrates a top plan view of an example solid-state thermal energy storage and dissipation element of one or more embodiments described herein;

FIG. 3D illustrates a top plan view of an example solid-state thermal energy storage and

dissipation element of one or more embodiments described herein;

FIG. 3E illustrates a top plan view of an example solid-state thermal energy storage and dissipation element of one or more embodiments described herein;

FIG. 3F illustrates a top plan view of an example solid-state thermal energy storage and dissipation element of one or more embodiments described herein;

FIG. 4A illustrates a top plan view of an example solid-state thermal energy storage and dissipation element of one or more embodiments described herein;

FIG. 4B illustrates a top plan view of an example solid-state thermal energy storage and dissipation element of one or more embodiments described herein;

FIG. 4C illustrates a top plan view of an example solid-state thermal energy storage and

dissipation element of one or more embodiments described herein;

FIG. 5A illustrates a top plan view of an example solid-state thermal energy storage and dissipation element of one or more embodiments described herein;

FIG. 5B illustrates a top plan view of an example solid-state thermal energy storage and dissipation element of one or more embodiments described herein;

FIG. 5C illustrates a top plan view of an example solid-state thermal energy storage and dissipation element of one or more embodiments described herein;

FIG. 6A illustrates a top plan view of an example solid-state thermal energy storage and dissipation element of one or more embodiments described herein;

FIG. 6B illustrates a top plan view of an array of solid-state thermal energy storage and dissipation element of one or more embodiments described herein;

FIG. 6C illustrates a front elevation view of an array of solid-state thermal energy storage and dissipation element of one or more embodiments described herein;

FIG. 7 illustrates a front elevation view of a spatially tuned array of solid-state thermal energy storage and dissipation element of one or more embodiments described herein;

FIG. 8 illustrates a flow chart of an exemplary process that generates a design for an energy storage and dissipation component; and

FIG. 9 illustrates a schematic block diagram of one or more exemplary devices used to implement various embodiments.

### DETAILED DESCRIPTION OF THE INVENTION

The following detailed description describes currently contemplated modes of carrying out exemplary embodiments. The description is not to be taken in a limiting sense, but is made merely for the purpose of illustrating the general principles of some embodiments, as the scope of the disclosure is best defined by the appended claims.

Various features are described below that can each be used independently of one another or in combination with other features. Broadly, some embodiments generally provide ways to dissipate and/or store thermal energy via solid-state component.

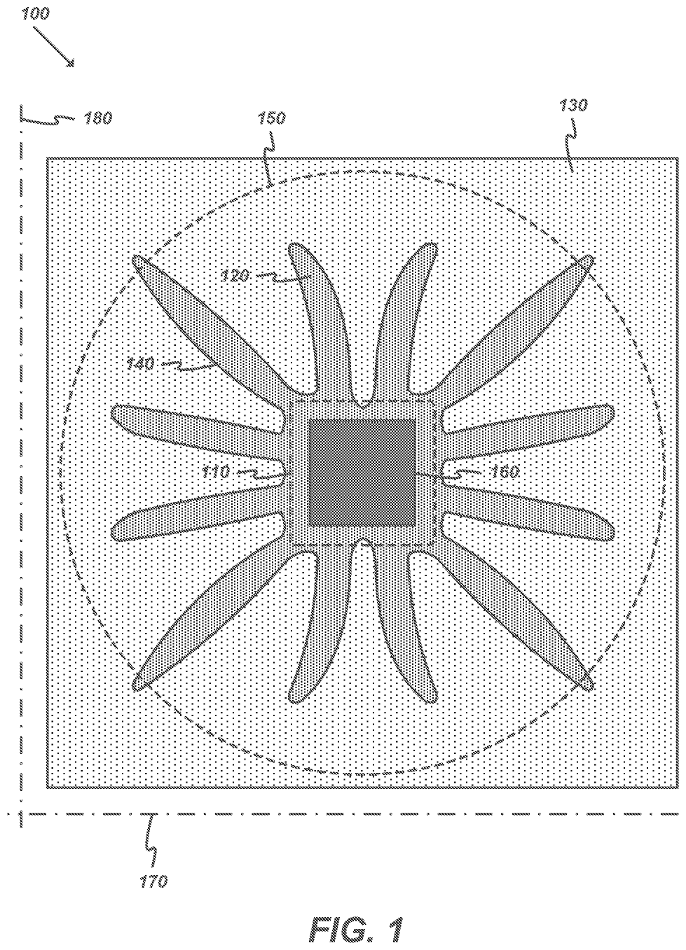

FIG. 1 illustrates an example solid-state thermal energy storage and dissipation element 100 of one or more embodiments described herein. A shown, solid-state thermal energy storage and dissipation element 100 may include a heat receiving section 110, a thermal conductor 120, an SS MT PCM 130, a thermal conductor/SS MT PCM interface 140, a thermal energy spreading section 150, a heat source 160, and/or other appropriate components.

Solid-state thermal energy storage and dissipation element 100 may be configured to effectively and efficiently dissipate thermal energy (heat) from heat source 160. Solid-state thermal energy storage and dissipation element 100 may be a composite including various types of materials, including a thermally-conductive material that may form the thermal conductor 120 and an SS MT PCM 130. Solid-state thermal energy storage and dissipation element 100 integrates multiple technologies (e.g., substrates, heat spreaders, solid-solid PCMs) in a new and non-intuitive way to create a first-of-the-kind solid-state composite substrate with integrated thermal capacity.

Heat receiving section 110 may be a section of thermal conductor 120 that interfaces with heat source 160. Heat receiving section 110 has a square shape in this example, and may be sized and shaped for a particular heat source 160, as appropriate. Heat receiving section 110 may be thermally coupled to the heat source 160 in various appropriate ways (e.g., a portion of the heat receiving section 110 may directly contact a portion of the heat source 160).

Thermal conductor 120 may include heat receiving section 110, which may be in contact with heat source 160 in order to receive thermal energy from the heat source 160. Thermal conductor 120 may include thermal energy spreading section 150, which may provide multiple thermal conductivity pathways (e.g., fingers or dendrites) to pull thermal energy away from the heat receiving section 110 and distribute the heat into and/or throughout the entire solid-state thermal energy storage and dissipation element 100, especially, into and/or through the SS MT PCM 130.

Thermal conductor 120 may include any thermally conductive material which provides a high degree of thermal-energy conductivity (k), such as two hundred watts per meter-kelvin (W/mK) or more. In some embodiments, the thermally conductive material may be an electrically-conductive material having a high electrical conductivity (σ). For instance, σ may be no less than about 1.9×10⁵ S/m. The thermally conductive material may include various metals and/or alloys. The metals and/or alloys may include metals, elements and alloys thereof including gold (Au), silver (Ag), copper (Cu), aluminum (Al), manganese (Mn), nickel (Ni), zinc (Zn), tin (Sn), beryllium (Be), magnesium (Mg), carbon (C) and/or titanium (Ti) as just some non-limiting examples.

In some embodiments, the thermally-conductive material may not be electrically conductive, thus allowing components of the solid-state thermal energy storage and dissipation element 100 (and/or the heat source 160) to be electrically isolated. Such materials may include various ceramics and intermetallic metals which have high thermal conductivity but are poor electrical conductors. For instance, such materials may be, or include, graphene, diamond, boron nitride, or gallium nitride, as non-limiting examples. In some embodiments, the thermally-conductive material may be or include semiconductor material, that may provide a potential coefficient of thermal expansion matching electronic and/or photonic devices and allow removal of additional solder connections and thermal resistances (if the electronic and/or photonic device(s) are integral to the semiconductor material). Such semiconductor material may include silicon, gallium arsenide, boron arsenide, and silicon carbide, as non-limiting examples. In addition, the metals, semiconductors and other thermally conductive materials may be configured in a vapor chamber or heat pipe configuration with effective thermal conductivities exceeding four hundred to one thousand W/mK.

The arrangement and/or configuration of thermal conductor 120 is important for thermal energy dissipation. To that end, the thermal conductor 120 may generally include a heat receiving section 110 and a thermal energy spreading section 150. The heat receiving section 110 may be configured to be in contact with a heat source 160 so as to receive thermal energy from the heat source 160. The solid-state thermal energy storage and dissipation element 100, and more particularly the heat receiving section 110, may be judiciously sized to generally conform to the outer dimensions or so-called “footprint” of the heat source 160. In this example, heat receiving section 110 may have a cuboid shape that may conform to a semiconductor chip heat source 160.

Thermal conductor 120 may include multiple dendrites as shown. As used herein, the term “dendrite” may refer to a finger-like structure. Dendrites may appear similar to the tree-like structures which form as crystals grow as a liquid/molten metal solidifies (referred to as “dendrites” in the metallurgical arts). The dendrites may connect to the heat receiving section 110 and outwardly expand away in various directions toward the perimeter of solid-state thermal energy storage and dissipation element 100. Each dendrite may gradually narrow to a point as the dendrite extends outwardly. The extension may be straight or wavy. The dendrites may appear like tentacles of an octopus. The dendrites may emanate radially outward from the heat receiving section 110 to improve heat conduction into the lower conductivity SS MT PCM 130. The number of dendrites may vary from as few as two, up to 50 or even more.

Attributes of the dendrites (e.g., length, width, height, depth, material, waviness or path, number of, arrangement, spacing, etc.) may be preferably optimized as described below for heat dissipation. In some embodiments, the dendrite structures may have a tree or fractal pattern in which additional dendrites continually branch from previous dendrites, much like branches or leaves of a tree. The number, shape and/or size of the dendrite structures may be optimized for heat distribution away for a particular heat source 160.

In some embodiments, the dendrites may only extend in substantially two dimensions (e.g., the x- and y-directions, along X-axis 170 and Y-axis 180, respectively). The dendrite structure may have generally the same cross-section in the other dimension (e.g., the z-direction), such that the dendrites may be columnar. In some embodiments, the dendrite structure may protrude and/or extend in all three dimensions (e.g., the x-, y- and z-directions).

SS MT PCM 130 may include various PCMs for passive thermal energy storage to manage the energy intermittency of associated systems. PCMs are materials that undergo a phase transition with an associated enthalpy, requiring an input of heat to drive transformation from a low temperature to high temperature phase. The heat input used by the transformation is thereby absorbed without a corresponding rise in temperature, as would be the case during sensible heating where the change in temperature from input heat is proportional to the heat capacity (Cₚ) of the material. When the transformation reverses upon cooling, the enthalpy of transformation is negative, releasing additional heat energy back into the material and slowing the cooling process accordingly. Such materials offer a compact, passive approach to enabling emerging and future high power pulse capabilities without overdesigning a system based on steady state max power requirements.

In this patent application disclosure, we detail embodiments of a device structure and method by which the device structure is made that simultaneously spreads and stores heat for high power, high efficiency, thermal energy storage and transient thermal buffering. The embodiments shown and described herein show the impact of using a high thermal conductance medium (e.g., thermal conductor 120) in combination with solid-to-solid PCM (e.g., SS MT PCM 130), and offers insight to the guided design for efficient geometries allowing optimal spreading of heat without sacrificing substantial thermal energy storage capacity. As exemplary embodiments, a nickel titanium alloy may be used as the PCM. Various other materials may be used as a PCM, as shown in Table 1 below. The PCM may undergo a reversible thermally induced or stress-induced transformation from an interpenetrating cubic structure (referred to as the parent austenite phase) to a complex monoclinic crystal structure (known as the martensite phase). In the context of PCMs and thermal energy storage (TES), the phase transformation results in a large change in enthalpy, which may be used to store thermal energy.

“Solid-state (SS)”, as used herein, may refer to a substance or material that remains a solid throughout normal and/or anticipated operating temperatures. And, “phase changing material (PCM)” may refer to a substrate or material that is able to change phases in response to a thermal input. Phase changes may include changes in matter states, such as: gas/vapor↔liquid, liquid↔solid, and solid ↔gas/vapor. Phase changes may also include phase changes within one matter state, most notably, solid (phase 1)↔solid (phase 2). For purposes of this disclosure, a “solid-state (SS) phase change material (PCM)” may be limited to substances and material which exhibit the latter phase change within a solid.

A subset of SS PCMs, which are used in embodiments of the present invention, are martensitic phase transformation PCMs. For purposes of this disclosure, “SS MT PCM” may refer to a material which undergoes a solid-solid martensitic transformation from one crystalline structure to another different crystalline structure during a change in temperature in the normal and/or anticipated operating temperatures. As further used herein, and according to conventions in the literature, the term “martensitic transformation (MT)” may be generally used to refer to any of the solid-solid phase transformations. These phase transformations may involve, but are not necessarily limited to, the B2, R-phase, B19, and B19′ martensitic phases for instance. Intermediate R-phase and B19 transformations are also possible. The martensitic transformation may occur in one or more steps.

Because they are always solid, MT PCMs do not require encapsulation, thus improving ease of use from an engineering perspective. In practice, structures may be fabricated that include approximately one hundred percent solid-to-solid phase change material, which is advantageous for high capacity and/or high power thermal applications.

The isothermal phase transition that occurs in SS MT PCMs may temporarily result in a very high thermal capacitance, thus allowing thermal energy storage at a preferred temperature with minimal material weight and volume. Initially, at the low temperature solid phase, the SS MT PCM may exhibit a sensible temperature rise, according to the standard specific heat formula provided in equation (1) below:

$$q = {mC}_{p} Δ T , \qquad ( 1 )$$

where q is the heat energy (J), m is the mass of material (kg), Cₚ is the specific heat constant for the material (J/kgK), and ΔT is the change in temperature (K).

The material may go through an isothermal phase change at a phase change temperature, TC, according to the latent heat formula provided in equation (2) below:

$$q = m L , \qquad ( 2 )$$

where q is the heat energy (J), m is the mass of material (kg), and L is the specific latent heat of the material (J/kg). At this point, there is essentially no change in temperature but the material continues to absorb a great deal of heat. The change in phase of the SS PCM may change the entropy of the material, resulting in an endothermic or exothermic response. Once the material has transitioned to the high temperature phase, the material may once again exhibit a sensible temperature rise, according to the specific heat formula of equation (1). This phenomena is generally the same for all SS MT PCMs.

The SS MT PCM may include a “shape memory alloy” (SMA) in some embodiments. SMAs may include one or more of: a binary shape memory alloy, a ternary shape memory alloy, a quaternary shape memory alloy, a higher-order alloyed shape memory alloy, or any other material which can readily change phase while remaining solid at normal and/or anticipated operating temperatures.

The nickel-titanium alloy system, known as NiTi or Nitinol, is one of the best known SMA materials which may be used in embodiments disclosed herein. The nickel-titanium SMA may be formed of an alloy of nickel and titanium, where the two elements are present in roughly equal atomic percentages, typically fifty to fifty-one percent nickel by atomic percent (or fifty-five to fifty-six percent by weight). Different alloys thereof may be named according to their weight percentage of nickel (e.g., Nitinol 55). In general, for Nitinol-based SMAs, the more titanium-rich (less nickel), the higher the transformation temperature.

Nitinol has been utilized for its unique elastically-induced phase transformation and shape memory properties. By contrast, embodiments of the present invention make use of a different property, the thermally-induced solid-to-solid phase transformations of Nitinol materials.

The specific thermal response characteristics will depend on the material. By changing composition from roughly fifty-one atomic percent nickel to forty-eight-and-one-half atomic percent nickel (where the balance of the material is titanium), the transformation temperature may be configured to range from roughly −70° C. to 100° C. From a caloric standpoint SS MT PCMs enable either cooler device temperatures for a given heat input or enable higher power or longer pulse duration for a given temperature rise. Both are overarching goals for electronic and photonic devices.

For instance, the high temperature parent phase of NiTi is cubic B2, and the lattice of the martensite is a monoclinic B19′ phase. The B19′ martensite can be obtained either by a single step transformation of B2→B19′, or by a two-step transformation of B2→R-phase→B19′ and/or B2→B19→B19′. R-phase has the Rhombohedral crystal structure, appears in some special cases, and depends on several factors like thermal history, cold work, solution treatment of the sample etc. It was found that in doped alloys, B19 can exist as an intermediate phase instead of R-phase. B19 is an orthorhombic phase (space group Pmmb). It is possible to induce partial or full transformations, including, but not limited to B2→R-phase, R-phase→B19′, B2→B19, B19→B19′, and B2→B19′. Because it is a reversible process, the opposite direction is also possible, for example R-phase→B2 (which would occur during cooling rather than heating as is the case in B2→R-phase). Of course, there are tradeoffs to any Martensitic transformation, such as going from B2→R rather than B2→B19′. For instance, the R-phase has some attracting properties like stability to thermal cycling and ageing, very small thermal hysteresis and very high fatigue life, etc.; however, the energy associated with the R-phase transformation is also small, generally leading to lower latent heat.

These near instantaneous, non-diffused, reversible, first-order transformations are more broadly referred to as a martensitic transformation and result in a lower symmetry through a distortion of the existing atomic lattice. This thermally induced distortion results in large enthalpy changes and corresponding volumetric latent heats approaching two hundred twenty-five MJ/m³. In addition to the high volumetric latent heat, materials that exhibit martensitic transformations have a number of attractive properties including high thermal conductivity, approaching one hundred fifty W/mK, excellent corrosion resistance, high strength and ductility, and good formability via traditional thermomechanical processing, machining, and manufacturing. Furthermore, the SMA transformation temperature, latent heat, thermal conductivity, and structural properties may be engineered by altering the Ni and Ti balance, alloying, and adjusting thermomechanical processing. This provides material configurability not generally possible with standard point-solution PCMs and, moreover, represents a class of robust, high thermal conductivity, commercially available materials of immediate interest for TES.

Generally, the phase transition process may be reversible. But in some applications, one may not need reversibility (e.g., the transition may be one-way). Consider one non-limiting example for high power microwave applications: devices may run until the devices “overheat” and ultimately expire. For example, a device running at maximum power may overheat and stop working. In that case, the SS MT PCM may be used to extend the duration that the device is able to run, if the SS MT PCM only transforms in one direction, such as from cold to hot (M→A).

The figure of merit (FOM) may be a quantifiable measure of relative PCM performance. (See T. Lu, “Thermal management of high-power electronics with phase change cooling,” International Journal of Heat and Mass Transfer, vol. 43, pp. 2245-2256, 2000, herein incorporated by reference in its entirety.) The FOM of a PCM may be defined as follows by equation (3):

$$FOM = ρ \times L \times {k}_{HT} , \qquad ( 3 )$$

where p is density, L is the latent heat of transformation, and k_{HT} is the thermal conductivity of the high temperature phase. In SI units, density p may be given in kg/m³; latent heat of transformation L may be given in J/kg; and thermal conductivity k_{HT} may be given in W/mK, and the resulting units of the FOM values should be ×10⁶ J²/Ksm⁴.

A high FOM represents a high volumetric heat capacity (ρ×L) and the ability to readily absorb and discharge thermal energy (k_{HT}). Indeed, these material properties and the resultant FOM are useful for expressing relative performance or efficiency for PCM materials in context of large-capacity and high-power thermal exchange and storage operations.

Table 1, below, lists some exemplary SS MT PCMs, transition temperatures, thermally induced latent heat, and FOM which may be used in embodiments of the present invention. Such SS MT PCMs may include shape memory alloys (SMA), ceramics or other metals and/or alloys, which are capable of obtaining both martensite and austenite structures. More particularly, the SMA may include a nickel-titanium-based alloy system, a copper-based alloy system, or magnetic alloys. The alloys may include one or more of: a binary shape memory alloy, a ternary shape memory alloy, a quaternary shape memory alloy, a higher-order alloyed shape memory alloy, or any other material which can readily change phase while remaining solid at normal and/or anticipated operating temperatures.

Various exemplary solid-state Martensitic transformation phase change materials, transition temperatures, thermally induced latent heat, and FOM are listed in Table 1 below.

TABLE 1

| | | Transition | | FOM |
|---|---|---|---|---|
| | | temperature | Latent heat | (×10⁶ |
| Material Class | Composition | (° C.) | L_{M-A} (J/g) | J²/(Ksm⁴)) |
| Martensitic | Ni_{47.73}Ti | 57 | 13.46 | 1478 |
| transformation | | | | |
| (Shape Memory | | | | |
| Alloy - NiTi- | | | | |
| based) | | | | |
| | Ni_{47.73}Ti* (R-phase | 40 | 4.54 | 498 |
| | transformation) | | | |
| . | Ni_{48.62}Ti | 90 | 27 | 2716-4876 |
| . | Ni_{49.5}Ti | 91 | 30.1 | 3028-5436 |
| . | Ni_{49.6}Ti | −3.8 | 18.3 | 1841-3304 |
| . | Ni_{49.63}Ti | 46.7 | 21.6 | 2173-3900 |
| . | Ni_{49.68}Ti | 81.9 | 31.7 | 3189-5725 |
| . | Ni_{49.74}Ti | 86.3 | 22.9 | 2304-4135 |
| . | Ni_{50.01}Ti | 52.7 | 27 | 2716-4876 |
| . | Ni_{50.13}Ti | −21.9 | 14.9 | 1499-2690 |
| . | Ni_{50.17}Ti | −39.1 | 9.1 | 915-1643 |
| . | Ni_{50.18}Ti | 47.2 | 26.7 | 2686-4822 |
| . | Ni_{50.21}Ti | 4.1 | 16.5 | 1660-2979 |
| . | Ni_{50.42}Ti | 17 | 23.3 | 2344-4207 |
| . | Ni_{50.49}Ti | 17.8 | 23.9 | 2404-4316 |
| . | Ni_{50.58}Ti | −10.8 | 18.8 | 1891-3395 |
| . | Ni₅₀Ti_{49.9}Cr_{0.1} | 89.25 | 30 | 3018-5418 |
| . | Ni₅₀Ti_{49.75}Cr_{0.25} | 63.25 | 23.7 | 2384-4280 |
| . | Ni₅₀Ti_{49.5}Cr_{0.5} | 42.35 | 23.3 | 2344-4207 |
| . | Ni₅₀Ti_{49.35}C_{50.65} | 33.2 | 21.3 | 2143-3846 |
| . | Ni₅₀Ti_{49.2}Cr_{0.8} | 13.05 | 20.8 | 2092-3756 |
| . | Ni₅₀Ti₄₉Cr₁ | −12.8 | 15.2 | 1529-2745 |
| . | Ni₅₀Ti_{48.75}Cr_{1.25} | −46.2 | 10.1 | 1016-1824 |
| . | Ni₅₀Ti_{49.9}V_{0.1} | 101.15 | 30.1 | 3028-5436 |
| . | Ni₅₀Ti_{49.75}V_{0.25} | 82.9 | 24.9 | 2505-4496 |
| . | Ni₅₀Ti₄₉V₁ | 64.5 | 23.2 | 2334-4189 |
| . | Ni₅₀Ti₄₈V₂ | 54.7 | 22.2 | 2233-4009 |
| . | Ni₅₀Ti₄₇V₃ | 35.9 | 16.9 | 1700-3052 |
| . | Ni₅₀Ti₄₅V₅ | 18.3 | 12 | 1207-2167 |
| . | Ni₅₀Ti₄₄V₆ | 15.15 | 10.6 | 1066-1914 |
| . | Ni₄₃Ti₅₂Cu₅ | 73.2 | 24.2 | 2435-4370 |
| . | Ni_{43.5}Ti_{51.5}Cu₅ | 77.6 | 24.7 | 2485-4460 |
| . | Ni₄₄Ti₅₁Cu₅ | 77.75 | 24.1 | 2424-4352 |
| . | Ni_{44.25}Ti_{50.75}Cu₅ | 73.95 | 25.9 | 2606-4677 |
| . | Ni_{44.5}Ti_{50.5}Cu₅ | 74.75 | 25.7 | 2585-4641 |
| . | Ni_{44.6}Ti_{50.4}Cu₅ | 77.9 | 29.1 | 2928-5255 |
| . | Ni_{44.75}Ti_{50.25}Cu₅ | 81.55 | 23.6 | 2374-4262 |
| . | Ni₄₅Ti₅₀Cu₅ | 80.65 | 29.3 | 2948-5291 |
| . | Ni_{45.2}Ti_{49.8}Cu₅ | 66.5 | 27 | 2716-4876 |
| . | Ni_{45.3}Ti_{49.7}Cu₅ | 57.15 | 25.2 | 2535-4551 |
| . | Ni_{45.5}Ti_{49.5}Cu₅ | 48.4 | 24.3 | 2445-4388 |
| . | Ni_{45.7}Ti_{49.3}Cu₅ | 30.05 | 21.7 | 2183-3919 |
| . | Ni_{45.9}Ti_{49.1}Cu₅ | 10.45 | 14.3 | 1438-2582 |
| . | Ni₄₆Ti_{49.1}Cu₅ | 2.7 | 16.8 | 1690-3034 |
| . | Ni_{46.1}Ti_{48.9}Cu₅ | −7 | 19.4 | 1952-3503 |
| . | Ni_{46.2}T_{148.8}Cu₅ | −21.4 | 14 | 1408-2528 |
| . | Ni_{47.5}Ti₅₀Cu_{2.5} | 94.2 | 31 | 3119-5598 |
| . | Ni_{42.5}Ti₅₀Cu_{7.5} | 76.8 | 27.9 | 2807-5038 |
| . | Ni_{49.8}Ti_{48.2}Hf₂ | 103.5 | 29.3 | 2948-5291 |
| . | Ni_{49.8}Ti_{46.2}Hf₄ | 114.65 | 29.1 | 2928-5255 |
| . | Ni_{49.8}Ti_{44.2}Hf₆ | 128.35 | 29.1 | 2928-5255 |
| . | Ni_{49.8}Ti_{42.2}Hf₈ | 160.2 | 30.3 | 3048-5472 |
| . | Ni_{49.8}Ti_{40.2}Hf₁₀ | 178.6 | 29 | 2917-5237 |
| . | Ni_{49.8}T_{139.2}Hf₁₁ | 189.45 | 29.3 | 2948-5291 |
| . | Ni_{49.8} T_{135.2}Hf₁₅ | 248.45 | 31.3 | 3149-5652 |
| . | Ni_{49.8}Ti_{30.2}Hf₂₀ | 330.2 | 35.1 | 3531-6339 |
| . | Ni₄₅Ti₅₀Pd₅ | 72.2 | 25.8 | 2595-4659 |
| . | Ni₄₃Ti₅₀Pd₇ | 66.2 | 23.8 | 2394-4298 |
| . | Ni₄₁Ti₅₀Pd₉ | 63.25 | 18.4 | 1851-3323 |
| . | Ni₃₀Ti₅₀Pd₁₁ | 68.15 | 14.5 | 1458-2618 |
| . | Ni₃₇Ti₅₀Pd₁₃ | 86.05 | 16.4 | 1650-2961 |
| . | Ni₃₅Ti₅₀Pd₁₅ | 99.35 | 17.7 | 1780-3196 |
| . | Ni₃₃Ti₅₀Pd₁₇ | 118.45 | 18.7 | 1881-3377 |
| . | Ni₂₉Ti₅₀Pd₂₁ | 160.45 | 21.6 | 2173-3900 |
| . | Ni₂₀Ti₅₀Pd₃₀ | 267.85 | 29.7 | 2988-5363 |
| . | Ni_{49.5}Ti_{49.5}Zr₁ | 100.6 | 30.6 | 3078-5526 |
| . | Ni_{49.5}Ti_{47.5}Zr₃ | 102.7 | 23.3 | 2344-4207 |
| . | Ni_{49.5}T_{145.5}Zr₅ | 104 | 27 | 2716-4876 |
| . | Ni_{49.5}T_{140.5}Zr₁₀ | 142 | 27.3 | 2746-4930 |
| . | Ni_{49.5}T_{135.5}Zr₁₅ | 221.65 | 28.8 | 2897-5201 |
| . | Ni_{49.5}T_{130.5}Zr₂₀ | 322.55 | 35 | 3521-6321 |
| . | Ni_{28.5}Ti_{50.5}Pt₂₁ | 330.85 | 22.4 | 2606-4677 |
| . | Ni_{43.5}Ti₅₀Cu₅Co_{1.5} | 53.85 | 25.9 | 2606-4677 |
| . | Ni₄₂Ti₅₀Cu₅Co₃ | 30.2 | 23.8 | 2394-4298 |
| . | Ni₄₀Ti₅₀Cu₅Co₅ | −5.35 | 21.6 | 2173-3900 |
| . | Ni_{42.9}Ti₅₀Cu₅Pd_{2.1} | 66.35 | 14.9 | 1499-2690 |
| . | Ni_{41.9}Ti₅₀Cu₅Pd_{3.1} | 73.1 | 16 | 1609-2889 |
| . | Ni_{39.2}Tis₀Cu₅Pd_{5.8} | 67.45 | 14.2 | 1428-2564 |
| . | Ni_{38.3}Ti₅₀Cu₅Pd_{6.7} | 65.65 | 13.6 | 1368-2456 |
| | Ni_{32.2}Ti₅₀Cu₅Pd_{12.8} | 59.85 | 12.3 | 1237-2221 |
| Martensitic | CuAlNi | variable | 6.8 | ~6000 |
| transformation | | | | |
| (Shape Memory | | | | |
| Alloy - Cu- | | | | |
| based) | | | | |
| | CuZnAl | variable | 6.2 | ~6000 |
| | CuAlMn | variable | 5.0 | ~6000 |
| | CuZnSn | variable | 4.5 | ~6000 |
| Martensitic | NiMnSnCu | variable | variable | variable |
| transformation | | | | |
| (Shape Memory | | | | |
| Alloy - | | | | |
| magnetic/Heusl | | | | |
| er alloys) | | | | |
| | NiMnTi | variable | variable | variable |
| | NiMnGa | variable | variable | variable |
| | NiMnSbCo | variable | variable | variable |
| | NiMnSn | variable | variable | variable |
| | NiMnIn | variable | variable | variable |
| | NiFeGa | variable | variable | variable |
| | NiFeGaCo | variable | variable | variable |
| | CoNiAl | variable | variable | variable |
| Martensitic | Zirconia | N/A | N/A | N/A |
| transformation | | | | |
| (Ceramics) | | | | |
| | Zirconia (Mg-PSZ) | N/A | N/A | N/A |
| | Zirconia (Y-TZP) | N/A | N/A | N/A |
| | Zirconia (Ce-TZP) | N/A | N/A | N/A |
| Martensitic | Steel | 727 | 70 | 28,175 |
| transformation | | | | |
| (Other Metals | | | | |
| and alloys) | | | | |
| | FeC | N/A | N/A | N/A |
| | CsCl | 479 | N/A | N/A |

Returning to FIG. 1, the SS MT PCM 130 may preferably be in contact with and surrounding the thermal conductor 120. The SS MT PCM 130 may be configured to readily undergo a solid-solid martensitic transformation from one crystalline structure to another different crystalline structure during a change in temperature in the normal and/or anticipated operating temperatures of the distributed thermal energy from the heat source 160 via the heat receiving section 110. Neither of the crystalline structures requires physical deformation to achieve the transformation. The SS MT PCM 130 may only use thermally induced solid-to-solid phase transformations. The SS MT PCM 130 may be selected from any of the materials listed in Table 1, above, in various embodiments. Other materials, though, may be used for the SS MT PCM 130, which provide similar capabilities.

Thermal conductor/SS MT PCM interface 140 may be both mechanically robust to maintain a single composite structure, and thermally conductive to ensure effective heat spreading. In general, a greater area (or volume) of thermal conductor/SS MT PCM interface 140 helps to increase the available pathways from the thermal conductor 120 to the SS MT PCM 130. There are tradeoffs though, such as increasing the design complexity to accommodate higher surface area for the thermal conductor/SS MT PCM interface 140. Optimization may be used to design the thermal conductor/SS MT PCM interface 140.

Thermal energy spreading section 150 is delineated as a simple circle for ease of illustration. Thermal energy spreading section 150 may follow the outline of the dendrites associated with thermal conductor 120.

The thermal energy spreading section 150 may provide pathways that are highly thermally conductive in order to pull thermal energy (heat) away from the heat receiving section 110 and distribute the into and/or throughout the entire solid-state thermal energy storage and dissipation element 100. In some embodiments, the thermal energy spreading section 150 may surround multiple dendrite structures, which penetrate into and/or permeate through the SS MT PCM 130 as shown.

In some embodiments, the thermal energy spreading section 150 may be further configured as a heat transfer surface, a heat exchanger, a heat spreader, a heat sink, a heat or cold plate, a condenser, a radiator, a fin or fins, or a fluidic channel for certain heart exchange application. Thermal energy spreading section 150 may be configured to include one or more heat pipes, vapor chambers, and/or other two-phase cooling apparatus in some embodiments.

Heat source 160 may be any component which generates thermal energy (or heat). Some examples may include electronic, photonic, and microchip devices. In some embodiments, the heat source 160 may be incorporated into or be a part of the solid-state thermal energy storage and dissipation element 100. In some embodiments, the heat source 160 and the solid-state thermal energy storage and dissipation element 100 may be separately supplied and later used together; thus, the heat source 160 might not always be considered a component of the solid-state thermal energy storage and dissipation element 100. The solid-state thermal energy storage and dissipation element 100 may serve as a substrate for supporting or mounting heat source 160 devices, such as electronic, photonic, microchip, and/or other types of devices with high conductivity heat spreading.

The heat source 160 may connect (or bond) to heat receiving section 110 of the thermal conductor 120 of heat receiving section 110 in various different ways, such as via a press fit, chemical bond, adhesive, or solder, as just a few examples. Various bonding techniques are well-known in the art and vary based on the heat source. These techniques may be used with the solid-state thermal energy storage and dissipation element 100.

X-axis (also referred to as the “horizontal” axis) is represented by line 170. Y-axis (also referred to as the “vertical” axis) is represented by line 180. Y-axis 180 is perpendicular to x-axis 170. A z-axis may be perpendicular to the x-axis 170 and the y-axis 180 (i.e., the z-axis may extend into and out of the page in this view).

Solid-state thermal energy storage and dissipation element 100 may have a quarter symmetry design as shown, such that, for example, the heat receiving section 110, the thermal conductor, and the SS MT PCM 130 are symmetrical about a center line that is parallel to x-axis 170 and a center line that is parallel to y-axis 180.

In the solid-state thermal energy storage and dissipation element 100, the amount of the thermally conductive material included in the thermal conductor 120 with respect to the solid-state thermal energy storage and dissipation element 100 may be defined as the percentage (%) of fill of material (also referred to as simply “% fill” or “percent fill”). Thus, a thirty percent fill of Cu, means there is thirty percent Cu (forming the thermal conductor 120), by volume, in the solid-state thermal energy storage and dissipation element 100. And thus, the SS MT PCM 130 provides the remaining seventy percent by volume. The percent fill might range from as little as five to ten percent to fifty percent, or perhaps even more. The percent fill may be tailored and/or optimized for expected heat load. If the design has a constant cross-section (e.g., in the z-axis direction) for the thermal conductor 120 and the SS MT PCM 130, then the percent fill of the thermal conductor 120 could correspond to the top area.

The remaining seventy percent by volume may be fabricated, for instance, by additive manufacturing (AM) techniques to selectively apply the two distinct materials used for the thermal conductor 120 and the SS MT PCM 13. AM techniques may include selective laser melting, electron beam melting, or spark plasma sintering. Hybrid approaches may be utilized too, such as pressing and sintering of metal powders. Other techniques may be used as well. For instance, a block of material to be used for the SS MT PCM 130 may be machined to form a space or void which is later filled with material to form the thermal conductor 120. The machining could be electrical discharge machining to form the space or void in the SS MT PCM 130 material. The thermal conductor 120 material may fill the space or void via, for example, an injection molding technique.

Another exemplary fabricating process may use gas-atomized powder of the desired composition placed in a chamber where a laser will selectively melt the material under conditions suitable for fusion of the resulting material. The geometric configuration, herein the inverse of a dendritic structure optimized for maximal heat flow into the printed material, may be selectively exposed to the laser under these conditions, resulting in the SS MT PCM 130. Separately, the thermally conductive material used for the thermal conductor 120 may be manufactured via a similar method, or cut to shape via machining, water jet, or wire-electrical discharge machining (EDM) strategies, and inserted into the SS MT PCM 130 structure. The two components may be bonded together via press fit under temperatures (e.g., between two hundred and four hundred ° C.) and pressures (e.g., greater than one MPa) suitable to form a solid bond and highly conductive thermal conductor/SS MT PCM interface 140 between the two surfaces.

In some embodiments, the solid-state thermal energy storage and dissipation element 100 may have a thin plating (e.g., a thickness as little as a few microns) on one or both of the top and bottom surfaces thereof. The plating may be a metal to help promote bonding between the surface of the heat source 160 and the heat receiving section 110. Such a strategy relies on chemical bonds and promotes better thermal conductance between those two surfaces.

Solid-state thermal energy storage and dissipation element 100 will enable smaller/lighter weight commercial electric capabilities. The solid-state thermal energy storage and dissipation element 100 may serve as a high-performance replacement for the conventional substrate and heat sink components for a vast array of electrified systems. To name a few, this could serve emerging super capacitor chargers, DC-DC converters (and more generally power electronics), radio frequency (RF) amplifiers, laser diodes, and microprocessors. One premise of the design of the solid-state thermal energy storage and dissipation element 100 is improved thermal time constant matching, thus enabling tailorable thermal substrate solutions for existing and emerging pulse power applications. This promises reliable attachment and preferable conduction of heat away from the device as well as improved thermal capacity to enable longer pulse duration or improved duty cycle.

The solid-state thermal energy storage and dissipation element 100 may also be used for TES applications. These have been previously used for solar energy utilization, waste heat recovery, building air conditioning, electric energy storage, temperature-control of greenhouses, telecommunications and microprocessor equipment, kitchen utensils, insulating clothing and textiles for thermal comfort applications, biomedical and biological-carrying systems, and food transport and storage containers. Such applications and more are described in the following review papers: N. Jankowski and F. Mccluskey, “A review of phase change materials for vehicle component thermal buffering,” Applied Energy, vol. 113, pp. 1525-1561, 2014; and A. Fallahi, G. Guldentops, M. Tai, S. Granado-Focil and S. Van Dessel, “Review on solid-solid phase change materials for thermal energy storage: Molecular structure and thermal properties,” App. Therm. Eng., vol. 127, pp. 1427-1441, 2017, herein incorporated by reference in their entities. We note that neither one of these comprehensive PCM review papers make any mention of solid-solid thermal energy storage substrates (enabled by solid-solid PCMs).

PCMs may include organic solid-liquid PCMs, polymeric solid-solid PCMs, solid-liquid salt hydrate PCMs, and metallic solid-liquid PCMs. Organic SL materials have low FOMs. For instance, paraffin and 1-Octadecanol have Figures of Merit of approximately 23×10⁶ J²/Ksm⁴ and 27.3×10⁶ J²/Ksm⁴, respectively. While these and other typical solid-to-liquid (SL) polymeric PCMs offer a caloric benefit over aluminum and other sensible materials, they are not without their own challenges. These materials suffer from low thermal conductivity, ranging between one tenth and one W/mK, which limits heat transfer into and out of the material. Combined with the fact that SL-PCMs by definition melt upon heating, these favorable material energy densities are reduced in practical applications where encapsulation and thermal conductivity enhancement is needed. More specifically, current solid-liquid TES rely on metallic fin structures, high thermal conductivity additives, and/or encapsulation to provide mechanical support, prevent molten PCM leakage, and enhance poor PCM thermal conductivity.

There are low-temperature solid-liquid metallic PCMs that have higher FOM values, include some which are close to and may exceed that of NiTi. These include Roto136F (FOM=2,603×10⁶ J²/Ksm⁴) and Gallium (FOM=14,310×10⁶ J²/Ksm⁴). While they exhibit promising FOM, these PCMs pose various integration issues and thus could be problematic. For example, Gallium is known to exhibit extreme undercooling, down to negative one hundred eighty-three ° C., and is incompatible with standard encapsulation materials such as aluminum. As such, it is likely that gallium would not re-solidify upon cooling in a hot water application and could catastrophically damage ancillary plumbing and pump equipment if leakage were to occur. Moreover, the use of metallic SL PCMs would require a detailed understanding of thermophysical properties (latent heat, specific heat, and thermal conductivity), the nature of melting phenomena in these materials (namely undercooling, segregation, and volume change), compatibility with different encapsulation materials, and additional changes in composition, microstructure, and thermal properties with repeated cycles. These aspects of metallic solid-liquid PCMs are generally not well understood, and their integration could be problematic.

The solid-state martensitic transformation phase change materials include a range of NiTi-based SMA materials. The materials offer up to two orders of magnitude higher FOM relative to standard solid-solid PCMs and paraffin. The NiTi r.t. SS Martensite materials here have a comparable volumetric latent heat (ρ×L) to standard solid-solid PCMs and paraffin, however, they have significantly higher thermal conductivity k_{HT}.

Transformation temperatures ranging from negative fifty to five hundred ° C., latent heats up to 35.1 J/g, and austenite thermal conductivities from 15.6 to 28 W/mK have been reported for various NiTi-based SMA materials in the literature. These properties are strongly dependent on the Ni and Ti balance, ternary elements, and/or thermomechanical processing. For binary alloys with decreasing atomic % Ni, 50.2 to 48.6%, martensite start temperatures increase from negative thirty-nine to ninety ° C. Following this trend, latent heats also increase with decreasing Ni content in binary NiTi alloys, evolving from 9 J/g at −39° C. to 27 J/g at 90° C. By fixing the Ni atomic % at 50% and replacing Ti with increasing amounts of Cr and V, up to 1.25% and 6% respectively, the Martensite start temperature and latent heats increase from 10 J/g to 30 J/g in the temperature range of −50 to 100° C. In NiTiCu ternary alloys, if the Cu atomic % is kept constant at 5% and the Ni content is decreased from 46.2 to 43 atomic %, the Martensite transformation temperature and latent heat increase from −21° C. and 14 J/g to 80° C. and 29 J/g. NiTi, NiTiCr, NiTiV, and NiTiCu offer large latent heats, but their performance is generally limited to temperatures below 100° C.

Unlike more traditional SMAs above, NiTiHf, NiTiPd, NiTiPt, NiTiAu, and NiTiZr offer higher temperature operation. While small changes of several percent are sufficient to provide meaningful changes in the Martensite start temperatures and latent heats in the low temperature alloys described above, the high temperature alloy systems require higher additions of ternary elements to provide meaningful changes. For example, a change from 2 atomic % Hf to 20 atomic % Hf (with 49.8 atomic % Ni) is necessary to move the transition temperature and latent heat from 103° C. and 29 J/g to 330° C. and 35 J/g.

It has been theorized that the general trend described here for different NiTi-based alloys, whereby the maximum latent heat increases with increasing transformation temperature, can be attributed to a composition-dependent destabilization of the high-temperature cubic B2 Austenite lattice. This is caused by the inability of Ni antisite atoms to relax at high temperature, along with a stabilization of the monoclinic B19′ Martensite structure. A thorough review of the impact of alloying, grain size and combined effects of heat treatment and precipitates on NiTi phase stability is outside the scope of the disclosure but has been covered in detail elsewhere. (The '652 application further discussed the select tunability of the SS MT PCMs by modifying the composition and alloys, opening up broader applicability for a range of low and high temperature applications.)

Although originally associated with the transformation in quenched steels that leads to extraordinary increases in strength and hardness, and discussed here more specifically to shape memory alloys, martensitic transformations also occur in a number of minerals and ceramics. Reliant on similar solid-solid phase transformations, these materials, including steels, may additionally be used as solid-state phase change materials in context of the current invention.

Each of these sub-classes of SS MT PCMs have their own benefits as solid-state phase change materials. For example, ceramics are generally not conductive so they could be useful in environments where electrical isolation is needed. Metals, on the other hand, are electrically conductive and tend to have higher thermal conductivity and electrical conductivity, so they are more useful in applications requiring high rates of electrical and thermal transport. The thermal transfer fluid may be a liquid, vapor or gas.

This discussion and Table 1 are non-limiting and are meant to serve as a general tool for the selection and development of SS MT PCMs. System engineers and designers will need to weigh the pros and cons of respective solid-state material systems when designing TES systems.

Although martensitic PCMs have the highest known FOMs of solid-solid PCMs, there is still room for improvement using composite structures.

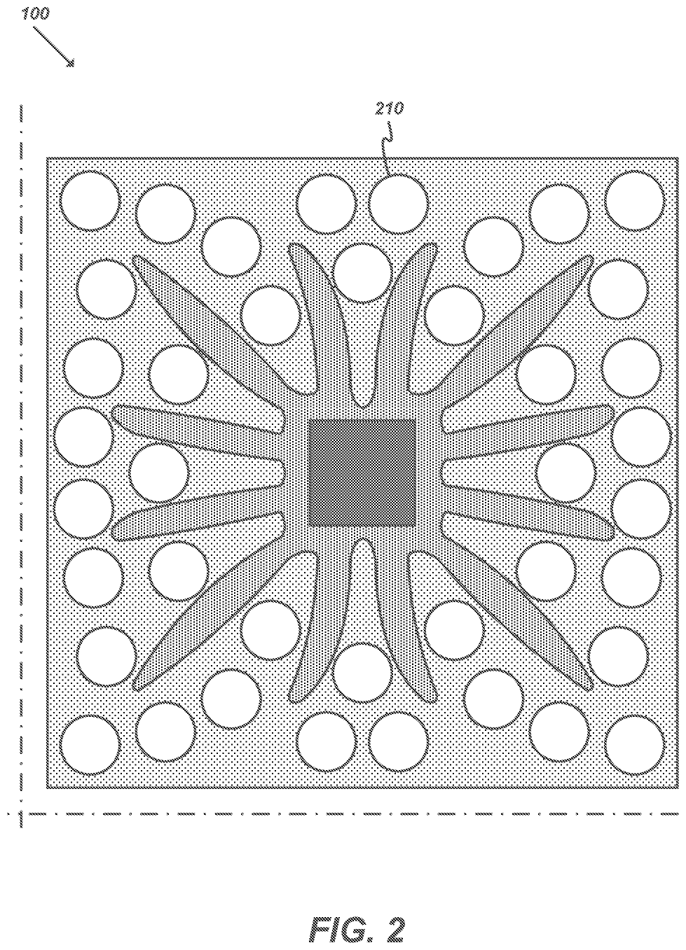

FIG. 2 illustrates an example solid-state thermal energy storage and dissipation element 100 with cooling elements 210 of one or more embodiments described herein. In this example, cooling elements 210 may be through-holes that may provide a path for fluid to pass. Cooling elements 210 may provide fluidic channels for passing a heat exchange fluid according to further embodiments of the present invention. The fluidic channels may range in size from order of ten nm across to up to an order of magnitude smaller than the width of the solid-state thermal energy storage and dissipation element 100 structure in some instances. The fluid may be air, water, hydrofluorocarbon, alcohol-derived solvents, metals or polymers in liquid state, or super-critical CO₂, among others, as non-limiting examples.

In some embodiments, solid-state thermal energy storage and dissipation element 100 may include embedded solid-liquid (SL) PCMs. Holes or bores in the SS MT PCM 130, such as cooling elements 210, may be provided for this purpose. The SL PCMs may be melted, poured into the holes or bores, and allowed to cool, thus filling the volume of the holes pr bores. The SL PCMs may be low-melting-point metals (such as gallium, bismuth, indium, tin, and their respective alloys), waxes, organic materials, salt-hydrates, or super-critical CO₂, among others, as non-limiting examples. The SL PCMs may range in size from one hundred nm across to up to an order of magnitude smaller than the width of the solid-state thermal energy storage and dissipation element 100 structure in some instances.

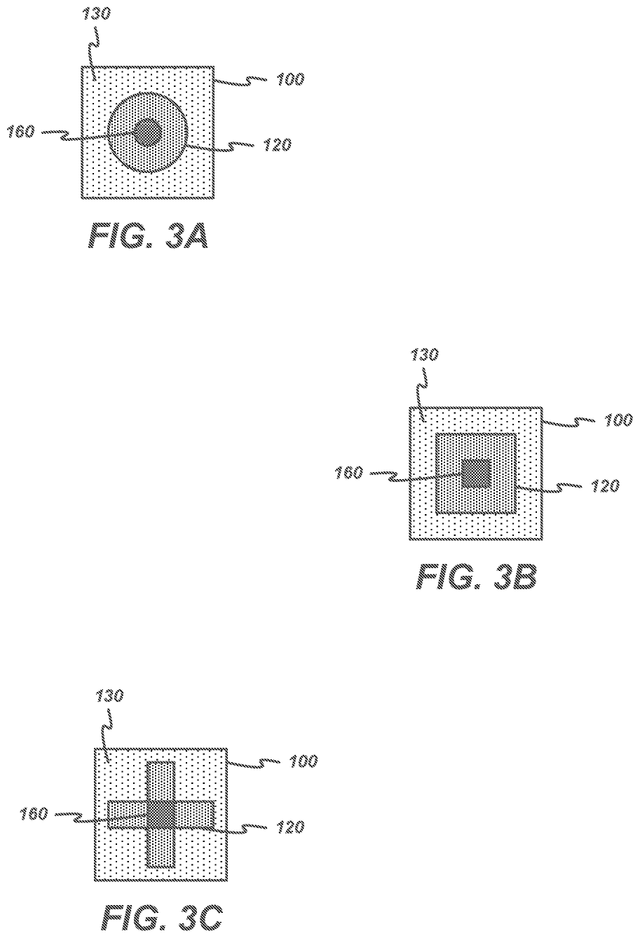

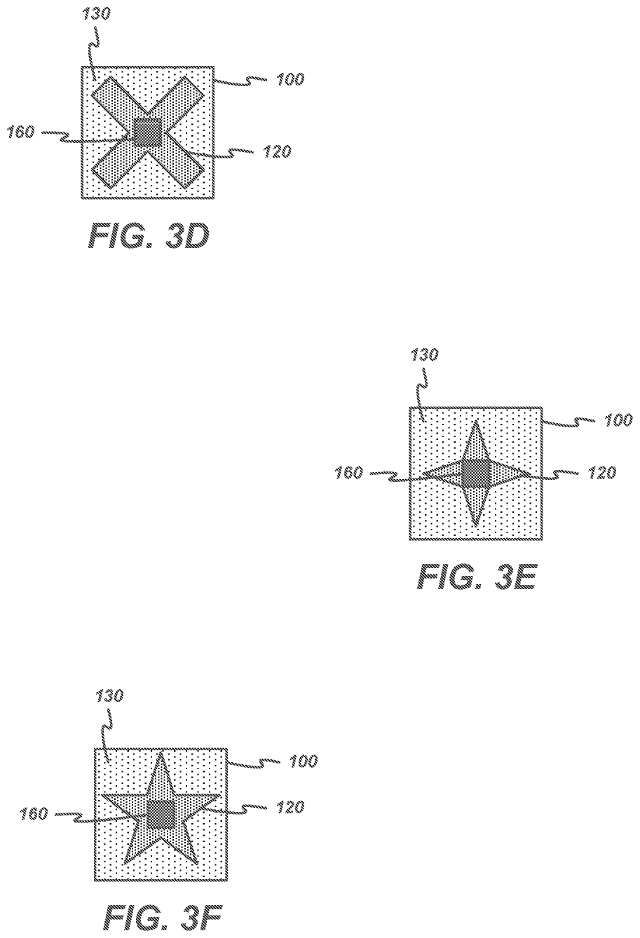

FIG. 3A illustrates a top plan view of an example solid-state thermal energy storage and dissipation element 100 of one or more embodiments described herein. FIG. 3B illustrates a top plan view of an example solid-state thermal energy storage and dissipation element 100 of one or more embodiments described herein. FIG. 3C illustrates a top plan view of an example solid-state thermal energy storage and dissipation element 100 of one or more embodiments described herein. FIG. 3D illustrates a top plan view of an example solid-state thermal energy storage and dissipation element 100 of one or more embodiments described herein. FIG. 3E illustrates a top plan view of an example solid-state thermal energy storage and dissipation element 100 of one or more embodiments described herein. FIG. 3F illustrates a top plan view of an example solid-state thermal energy storage and dissipation element of one or more embodiments described herein.

The examples of FIG. 3A-FIG. 3F include various alternative embodiments of the solid-state thermal energy storage and dissipation element 100 that do not include dendrites. These examples include simpler designs utilizing elements such as concentric shapes, crosses, and stars. Each of these examples includes a heat source 160, a thermal conductor 120, and an SS MT PCM 130. The heat receiving section 110 of each solid-state thermal energy storage and dissipation element 100 may approximate the perimeter of heat source 160 and the thermal energy spreading section 150 may emanate outwardly from the heat receiving section 110 and help pull heat and distribute heat into and/or throughout the SS MT PCM 130.

FIG. 3A shows a solid-state thermal energy storage and dissipation element 100 having a circular-shaped heat source 160; the thermal conductor 120 is similarly shaped, and is surrounded by the SS MT PCM 130. The shape of the SS MT PCM 130 is depicted as square but is not critical as the larger SS MT PCM 130 may function here as a heat sink. The larger area/volume of the thermal conductor 120 compared to the heat source 160 provides greater pathways to pull heat.

FIG. 3B shows a solid-state thermal energy storage and dissipation element 100 having a square-shaped heat source 160; the thermal conductor 120 is similarly shaped, and is surrounded by the SS MT PCM 130.

FIG. 3C shows a solid-state thermal energy storage and dissipation element 100 having a square-shaped heat source 160; the thermal conductor 120 has a cross shape, and is surrounded by the SS MT PCM 130. The four arms of the cross help pull heat into the SS MT PCM 130.

FIG. 3D shows a solid-state thermal energy storage and dissipation element 100 having square-shaped heat source 160; the thermal conductor 120 is shaped as an angled cross (rotated) 45°, and is surrounded by the SS MT PCM 130.

FIG. 3E shows a solid-state thermal energy storage and dissipation element 100 having a square-shaped heat source 160; the thermal conductor 120 is configured as a four-pointed star, and is surrounded by the SS MT PCM 130.

FIG. 3F shows a solid-state thermal energy storage and dissipation element 100 having square-shaped heat source 160; the thermal conductor 120 is configured as a five-pointed star, and is surrounded by the SS MT PCM 130. Other star designs may include additional star points.

While FIG. 3A-FIG. 3F show 2D structures, the structures may be extended in the third z-dimension forming a three-dimensional (3D) structure. For example, in FIG. 3A, thermal conductor 120 may be configured as a cylinder, sphere, or hemisphere structure which extends into and/or out of the page. In FIG. 3B, thermal conductor 120 may be configured as a cubic or prism structure which extends into and/or out of the page. In FIG. 3C and FIG. 3D, the cross arms could extend into and/or out of the page. In FIG. 3E and FIG. 3F, the star points could extend into and/or out of the page. The cross arms or star points may provide similar functionality to the dendrites of FIG. 1.

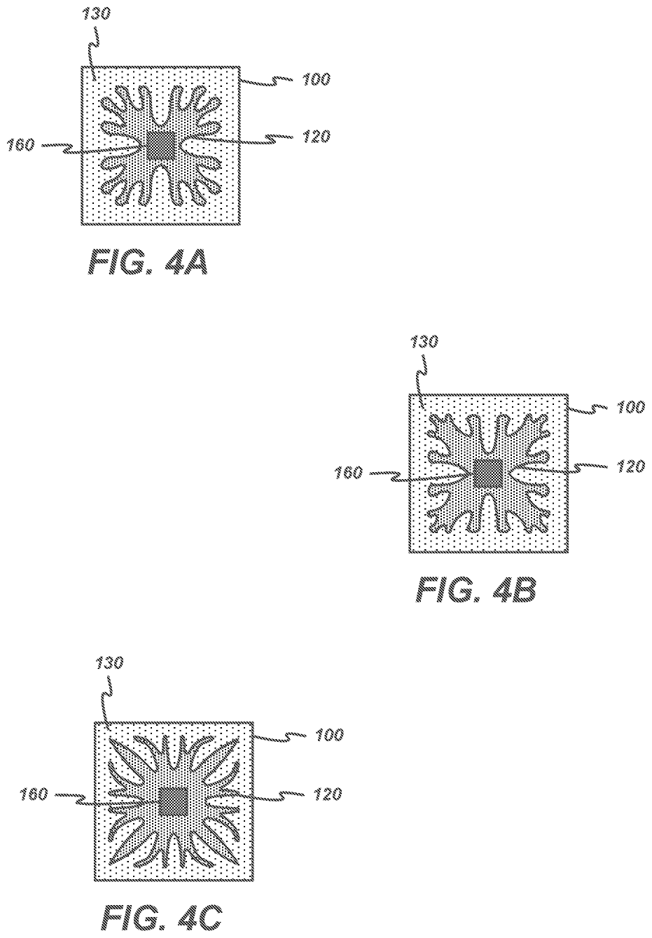

FIG. 4A illustrates a top plan view of an example solid-state thermal energy storage and dissipation element 100 of one or more embodiments described herein. This example may have a thirty percent fill of thermal conductor 120 relative to the SS MT PCM 130.

FIG. 4B illustrates a top plan view of an example solid-state thermal energy storage and dissipation element 100 of one or more embodiments described herein. This example may have a forty percent fill of thermal conductor 120 relative to the SS MT PCM 130.

FIG. 4C illustrates a top plan view of an example solid-state thermal energy storage and dissipation element 100 of one or more embodiments described herein. This example may have a fifty percent fill of thermal conductor 120 relative to the SS MT PCM 130. For reference, the example of FIG. 1 may have a ten percent fill of thermal conductor 120 relative to the SS MT PCM 130.

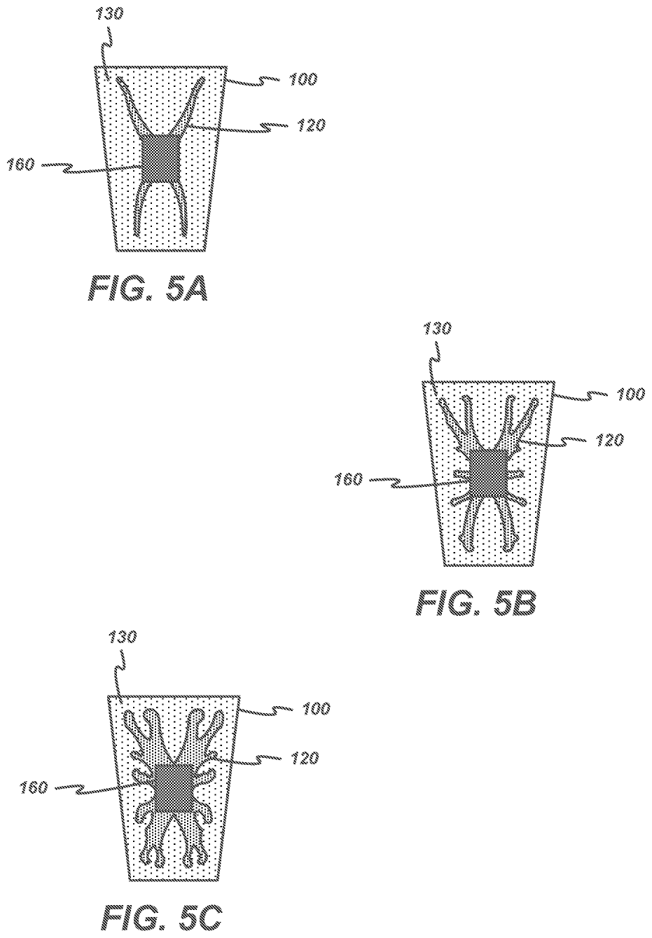

FIG. 5A illustrates a top plan view of an example solid-state thermal energy storage and dissipation element 100 of one or more embodiments described herein. FIG. 5B illustrates a top plan view of an example solid-state thermal energy storage and dissipation element 100 of one or more embodiments described herein. FIG. 5C illustrates a top plan view of an example solid-state thermal energy storage and dissipation element of one or more embodiments described herein. These examples include a trapezoid shaped SS MT PCM 130, as shown. Different embodiments may be implemented with various different shapes of SS MT PCM 130. The various examples shown here, and/or those described above, may be implemented in various 3D structures that extend elements such as thermal conductor 120, SS MT PCM 130, thermal conductor/SS MT PCM interface 140, and/or heat receiving section 110 along the z-axis.

FIG. 5A, FIG. 5B, and FIG. 5C show assembled composite structures for specified percent fills from ten to fifty percent, associated with fixed power on times from fifteen to seventy-five seconds. The ideal % fill of Cu decreases with increased on-time as the total thermal energy that needs to be stored increases, outweighing the benefits of a high conductivity, low-capacity composite, which is preferred when on-time is short. Note that the topology optimization algorithm may predict geometry as well as percent fill. When the percent fill variable is fixed at fifty percent, the geometry changes, favoring higher contact area between the NiTi and Cu for short on-times where conduction is the limiting factor.

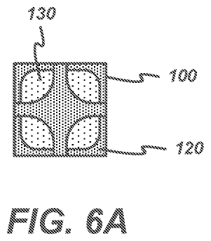

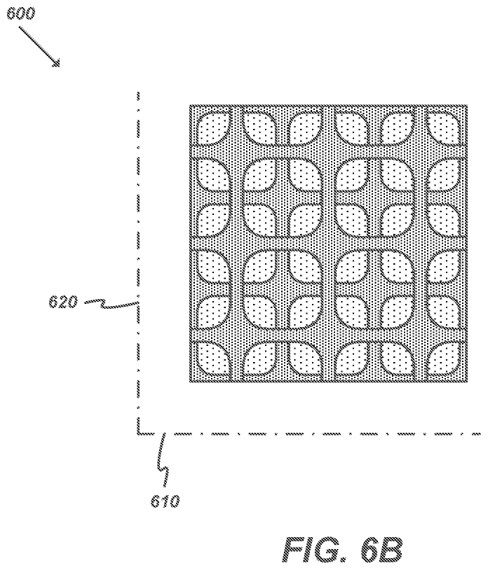

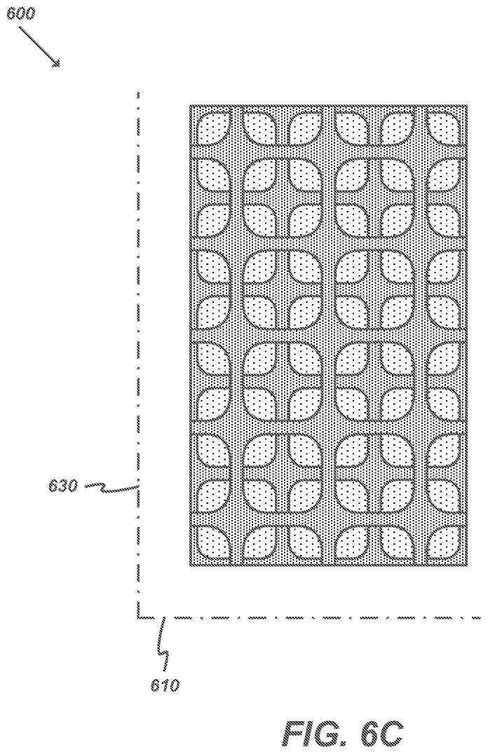

FIG. 6A illustrates a top plan view of an example solid-state thermal energy storage and dissipation element 100 of one or more embodiments described herein. In this example, the solid-state thermal energy storage and dissipation element 100 has a cubic shape and is symmetrical with respect to each face.

FIG. 6B illustrates a top plan view of an array 600 of solid-state thermal energy storage and dissipation element 100 of one or more embodiments described herein. FIG. 6C illustrates a front elevation view of the array 600 of solid-state thermal energy storage and dissipation element 100 of one or more embodiments described herein. The cubic solid-state thermal energy storage and dissipation element 100 may be arranged into various arrays of elements, having different sizes, shapes, etc. X-axis 610, y-axis 620, and z-axis 630 are provided as references to the cuboid structure of array 600. X-axis 610 is perpendicular to y-axis 620 and z-axis 630, y-axis 620 is perpendicular to x-axis 610 and z-axis 630, and z-axis 630 is perpendicular to x-axis 610 and y-axis 620.

Instead of the cubic structure of FIG. 6A, different embodiments may utilize lattice structures, graded lattices, and topology optimization structures for achieving spatially tuned thermal and structural properties according to some embodiments. Such elements may have a 3D shape that includes sets of repeating 3D unit cells, such as the cubic cell of FIG. 6A. For example, some embodiments may utilize a truss-based unit cell (not shown) or an implicit surface-based cell such as the cubic cell of FIG. 6A. The unit cells may be optimized graded lattices and structures for spatially-tuned k- and L-specific strength and specifical stiffness, among other tunable properties.

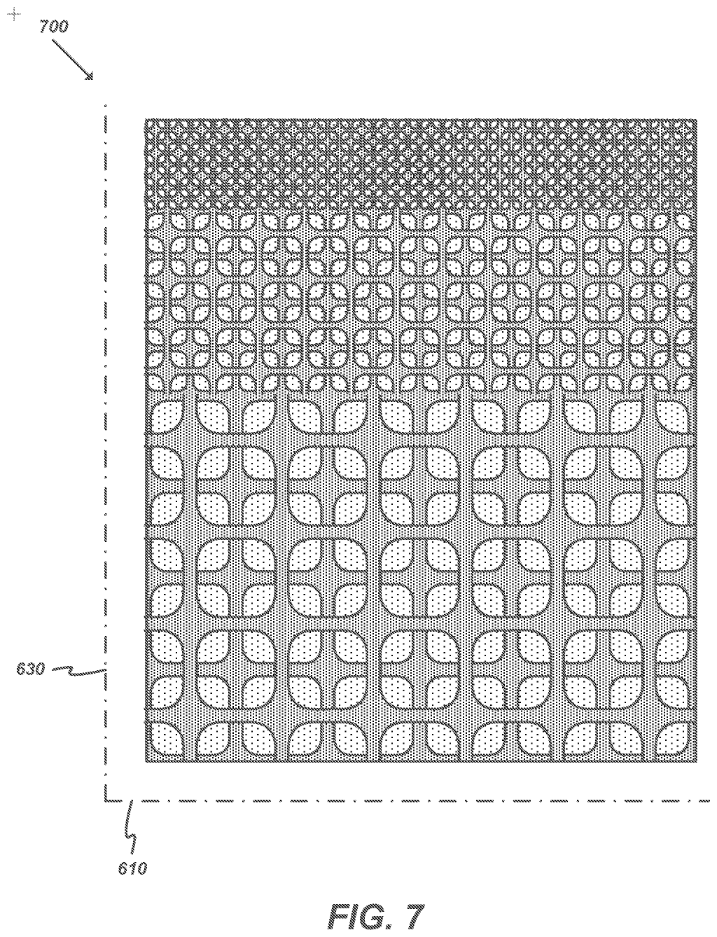

FIG. 7 illustrates a front elevation view of a spatially tuned array 700 of solid-state thermal energy storage and dissipation elements 100 of one or more embodiments described herein. The spatially tuned array 700 may have a square or rectangular shape when viewed from the top or bottom, similar to array 600. In this example, the size of the unit cells is reduced as the array 700 progresses along the z-axis 630. Different embodiments may include various different sizes and arrangements of unit cells, as appropriate.

The key differences between a truss-based cell and an implicit surface-based cell are that the implicit surface-based cells have much higher surface area to volume ratios, increasing the contact area between the conductor and the storage material, and that the implicit surfaces have a lot of complex curvature, making them more difficult to fabricate in practice.

The unit cells could be made of either the thermally conductive material used for thermal conductor 120 or the SS MT PCM 130 (in this example, the thermal conductor 120 forms the unit cells). Which one will depend on the exact materials selected and the fabrication methods used. In either case, the remaining volume may be filled with the other material. There is no interstitial space between the unit cells shown. By nature, unit cells can be tiled in 3D without any empty space between them—in the cases shown here the unit cells are cubic.

The lattice may be a graded version of the implicit surface-based lattice. For example, the lattice may be graded such that the size of the unit cell remains constant but the thickness of the implicit surface changes as it moves down such that the ratio of conductive material to PCM is changing. As another example, the lattice may be graded such that the size of the unit cell is getting larger as it goes down such that the pore size (to be filled with the other material) is increasing but the ratio of materials remains constant.

One or more heat sources 160 may be located on or possibly within the lattice structure. In practice, if these approaches are used with a chip as the heat source 160, there would likely be a pad approximately the size of said chip made entirely of the high conductivity material with latticed composite material surrounding it. This is likely to be on a surface, rather than the interior of the composite, since that chip will be connected to other electronics. Alternatively, a part may be made from the lattice-composite like a heat exchanger, where the heat source is a fluid pathway through that part (basically, this latticed composite is treated as a material from which the component is machined or assembled). It should also be noted that the unit cell size and ratio of conductor to PCM does not have to be fixed in 3D, the lattice characteristics may vary spatially.

These form factors should be considered non-limiting. In addition to the macroscopic composites shown previously, these composites can be produced at much larger and smaller length scales. As a non-limiting example, the composite could consist of a micro-scale or macro-lattice of martensitic PCM with a density of seventy percent with the remainder filled with high thermal conductivity metal. This lattice could be, for example, truss-based, a triply periodic minimum surface, or a random foam structure. The density of the PCM lattice does not have to be constant and could be designed as a gradient so that its ratio of thermal capacity to conductivity varies spatially. The composite could be designed around specific thermal load profiles. In this way, both the overall volume fraction of conductive versus storage material would vary spatially but also the thickness of the individual segments of material (e.g., truss diameters for a truss-based lattice).

Although simple form-factors are depicted herein with one hundred percent volumetric fill for conditions where passive convective cooling is the primary method of heat removal, this type of optimization can be performed in 3D for systems that may have different heat source geometries and heat removal mechanisms. One example structure would be a dual fluid flow heat exchanger, where separate hot and cold fluid loops flow through the device with the goal of maximizing heat transfer from the hot fluid. For steady-state conditions, this would mean designing the heat exchanger to minimize thermal resistance between the two fluids. For transient conditions, however, where the hot fluid is extracting heat from a dynamic source over a finite period of time, it may be beneficial to store some heat energy in the heat exchanger rather than maximizing heat flow through the exchanger and out to the cold fluid. Although the set of variables to consider is more complex, topology optimization methods or generative design methods may be used to predict the ideal composite material ratio and spatial distribution and, further, to predict the geometric form of the heat exchanger device as well.

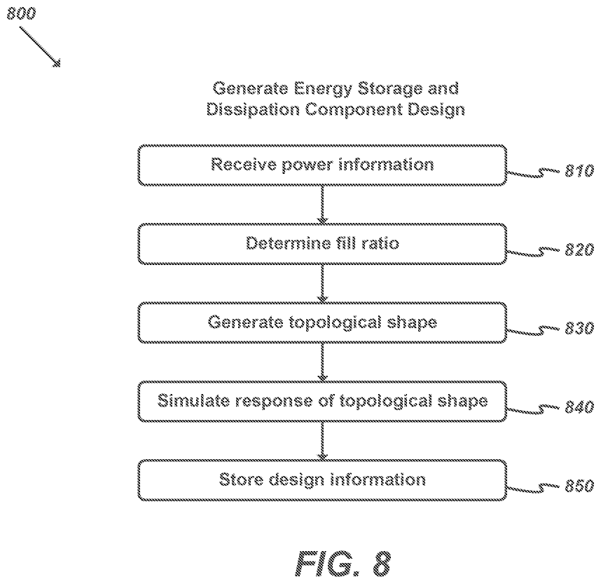

FIG. 8 illustrates an example process 800 for generating a design for an energy storage and dissipation component. The process may be used to generate a two-dimensional (2D) or 3D layout for a particular solid-state thermal energy storage and dissipation element 100. The process may determine a fill percent, generate a shape for the thermal conductor 120 and/or other components of the solid-state thermal energy storage and dissipation element 100 (e.g., the SS MT PCM 130, the heat receiving section 110, etc.). The process may be performed whenever a solid-state thermal energy storage and dissipation element 100 is developed. In some embodiments, process 800 may be performed by device 900 described below.

Design and fabrication of appropriate composite structures may utilize a three-step sequential process for additively manufactured NiTi materials. Step one is to develop transient topology optimization algorithms to enable full utilization of the additive manufacturability of the material. Step two is to identify manufacturing approaches for high latent heat solid-solid PCMs. Step three is to use these modeling and manufacturing approaches to develop high performance, state of the art solid-state thermal energy storage substrates.

There is a process involved in understanding how print parameters (in the case of additive manufacturing) and processing steps (choice of material composition, cold and hot working, post process heat treating, etc.) can affect part viability and functional properties. Before printing functional parts, there is a process of printing single track runs to identify regions of low-porosity and robust parts. If the power is too high, or too low, the laser is rastered too fast or too slow, or the hatch spacing is off parts may include various defects, such as keyhole defects, lack of fusion, and balling.

Once this process of identifying the processability map is complete, one-centimeter cubes may be manufactured and cut into squares and circular samples for xenon flash, differential scanning calorimetry, and microstructural characterization with transmission electron microscopy and similar tools.

With known material properties, namely density—latent heat transformation characteristics—thermal conductivity—and specific heat—a custom transient topology optimization script may be solved. This optimization solves the transient heat equation and minimizes temperature rise for a given input heat load and time. The algorithm will provide an optimum solution for a discrete heat source (or sources) for a specified or required transient operating condition.

With known material properties, predictive design algorithms may be used to generate optimal composites given a set of design criteria. For example, provided a heat source geometry, an output thermal power, a set of available materials, and a total design shape, and an objective function (such as minimization of temperature at the heat source surface), algorithms can be used to predict what materials, in what fractions, and with what geometries, will deliver the goal defined by the objective function. One method of doing this is topology optimization. It is not the only method of doing so, however. As a non-limiting example, generative design algorithms can be used to predictively, iteratively refine structures around a specific set of constraints.

A composite consisting of thirty percent Cu and seventy percent NiTi is predicted to have a FOM almost five times greater than NiTi on its own and a composite structure consisting of thirty percent superconducting heat spreader/vapor chamber is predicted to have a FOM of one hundred sixty thousand (almost fifty-three times greater than NiTi). In both cases this is due to the fact that conductivity increases at a much higher rate than latent heat decreases. The martensitic transformation material described here is for nickel titanium alloys (e.g., NiTi, NiTiCu) or the like. In other examples, the material could include, but is not limited to, NiTi, NiTiCu, AgCd, AuCd, CoNiAl, CoNiGa, CuAlBeX (X: Zr, B, Cr, Gd), CuAlNi, CuAlNiHf, CuSn, CuZn, CuZnX (X: Si, Al, Sn), FeMnSi, FePt, MnCu, NiFeGa, NiTiHf, NiTiPd, NiMnGa, TiNb, NiTiZr. The shape memory material includes binary and ternary shape memory materials having two or more phases, and accordingly one or more changes in phase when heated.

Likewise, the high conductivity element could be, as non-limiting examples, pure metals or alloy with primary constituents of Cu, Al, Mg, Be, or Au. It could be a high thermal conductivity electrical insulator like graphene, diamond, gallium nitride, boron nitride, or boron arsenide. It could be a two-phase heat spreading device like a heat pipe or vapor chamber, either encapsulated by the PCM material itself or encapsulated by a high conductivity solid such as, but not limited to, those listed above.

FOM is only a starting point for evaluating the performance of a PCM for a given application. The balance of properties needed to maximize performance is dependent on the total thermal energy to be stored and discharged, the heat flux at the interface between the heat source and the storage component, and the cycling time. For long cycle times with low heat fluxes but large total energies, volumetric or mass-specific latent heat will be most critical, since there is plenty of time for heat to be conducted away from the source and into the storage component. For high heat flux applications, reducing the temperature change at the heat source will require higher conductivity, even if it comes at the expense of heat storage capacity. When heat flux is high but cycle times are short, the total heat to be stored may not be that large, meaning that additional heat storage capacity is not required, regardless.

As shown, process 800 may include receiving (at 810) power information. Such power information may include information relevant to heat generation, such as maximum power, ambient power, on time or duty cycle, etc.

Process 800 may include determining (at 820) fill ratio or percentage. Such a determination may be made based on various algorithms and/or simulations as described here. In some embodiments, the fill ratio may be specified rather than determined (e.g., fifty percent).

The process may include generating (at 830) a topological shape. The topological shape may be generated using various modeling tools. The topological shape may be applied to the thermal conductor 120, SS MT PCM 130, and/or other appropriate components of the solid-state thermal energy storage and dissipation element 100.

As shown, process 800 may include simulating (at 840) response of topological shape. The heat dissipation of the generated shape may be simulated using various appropriate tools. Operations 820-840 may be performed iteratively in some embodiments, in order to converge on some desired performance characteristics.

Process 800 may include store (at 850) design information. The design information may include, for instance, listings of materials to be used for each component, percent fill, coordinate or other information that defines the shapes of features such as the thermal conductor 120, SS MT PCM 130, and/or other appropriate components of the solid-state thermal energy storage and dissipation element 100.

One of ordinary skill in the art will recognize that process 800 may be implemented in various different ways without departing from the scope of the disclosure. For instance, the elements may be implemented in a different order than shown. As another example, some embodiments may include additional elements or omit various listed elements. Elements or sets of elements may be performed iteratively and/or based on satisfaction of some performance criteria. Non-dependent elements may be performed in parallel. Elements or sets of elements may be performed continuously and/or at regular intervals.

Designs that include less copper are better suited for dissipating low heat flux whereas the designs that contain more copper are better able to dissipate high heat flux. This demonstrates that composite structures can be designed for specific transient use cases and that the ability to tune effective conductivity and capacity is an effective tool. Moreover, this demonstrates that the maximum FOM (while a useful tool for comparing one material or composite to another) is not completely capable of predicting performance for different composite designs. For example, the best FOM may be predicted at thirty percent Cu fill. However, experimental results demonstrate that the ideal fill percentage (and corresponding composite material properties) vary based on the applied heat flux. This result is a non-intuitive, but important practical consideration when designing these structures. The approach and methodology described herein provides a path towards developing ideal solid-state composite structures that are not possible to predict/arrive at via existing figures of merit or analytical composite material approaches.

The novel solid-state thermal energy storage and dissipation element 100 of some embodiments may provide various benefits with respect to existing solutions. For example, solid-state thermal energy storage and dissipation element 100 may eliminate voids associated with intermittent melt-thaw cycles of solid-liquid PCMs and/or may eliminate voids associated with high surface energy, high surface tension, and poor wetting in metal-liquid PCMs. The solid-state thermal energy storage and dissipation element 100 may include SS MT PCMs that do not need to melt to absorb latent heat, so system complexities associated with liquid containment and expansion are eliminated. The SS MT PCMs utilized by the solid-state thermal energy storage and dissipation element 100 are immune from phase segregation and settling, which is a susceptibility of PCM solutions or mixtures that go into a liquid phase. The solid-state thermal energy storage and dissipation element 100 may provide a reduction in packaging complexity when dealing with a solid-solid SS MT PCM.

While most PCM materials have a fixed melting temperature, SMA materials utilized by the solid-state thermal energy storage and dissipation element 100, can be compositionally tuned to undergo the solid-solid phase transformation at temperatures ranging from four K to over seven hundred seventy-three K. SMA materials can be fabricated using AM, opening the door to direct integration of solid-solid SMA PCM materials to form factors suitable for TES without additional post-processing. The AM capabilities also open the door for homogeneous/heterogenous/functionally graded integration of SS MT PCM materials but changing system process parameters and material composition. SMA materials are widely regarded for their biocompatibility and strength, so integration into worn TES applications and for use as combined TES/structural elements is possible. SMA materials are widely used as actuators, so combined thermal actuator/TES is possible. Some SMA materials have demonstrated very low thermal hysteresis upon subsequent heating and cooling (minimal supercooling), which is a known issue with standard PCM materials. The solid-solid phase change in SMAs is a fast/congruent first-order phase transformation, allowing TES for fast transients (such as those seen in electronic applications). SMA materials are RoHS-compliant and the constituents to make these materials are abundant. SMA materials with latent heats ranging from about 5-35KJ/kg (up to 225 MJ/m3) have been demonstrated in the literature. This is believed to be greater than any known solid-solid PCMs, and equivalent or greater than many other widely-used PCMs. Consistent with a point above, the yellow bands reiterate that SMA material composition can be tuned to provide solid-solid phase change at temperatures ranging from four K to above seven hundred seventy-three K. Unlike many paraffins and polymer-based solid-solid PCMs which have low thermal conductivity, SMA materials (metal alloys) inherently have high thermal conductivity. This makes heat transport and removal in these materials much better. SMA materials (metal alloys) have relatively high specific gravity, resulting in smaller PCM volume for a given heat storage. This allows miniaturization and size, weight, power, and cost (SWaP-C) improvements when designing TES systems.

The processes and modules described above may be at least partially implemented as software processes that may be specified as one or more sets of instructions recorded on a non-transitory storage medium. These instructions may be executed by one or more computational element(s) (e.g., microprocessors, microcontrollers, digital signal processors (DSPs), application-specific integrated circuits (ASICs), field programmable gate arrays (FPGAs), other processors, etc.) that may be included in various appropriate devices in order to perform actions specified by the instructions.

As used herein, the terms “computer-readable medium” and “non-transitory storage medium” are entirely restricted to tangible, physical objects that store information in a form that is readable by electronic devices.

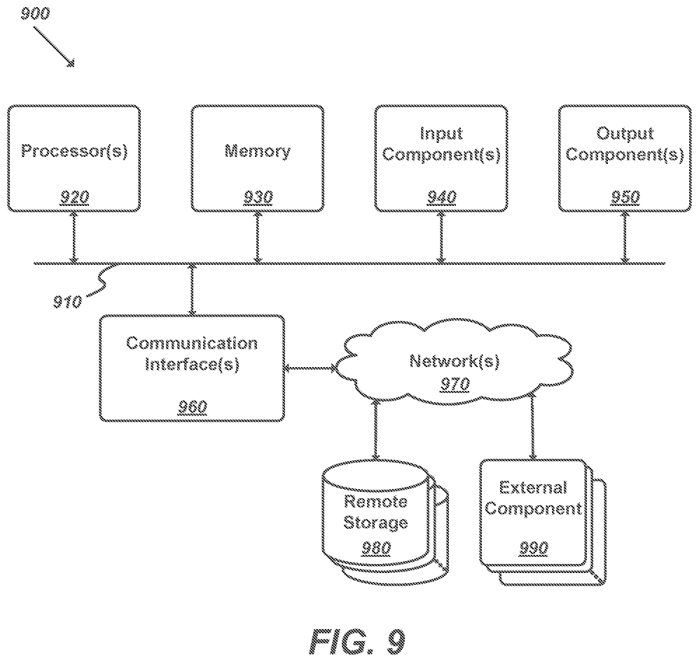

FIG. 9 illustrates a schematic block diagram of an exemplary device (or system or devices) 900 used to implement some embodiments. For example, the process described in reference to FIG. 8 may be at least partially implemented using device 900.

Device 900 may be implemented using various appropriate elements and/or sub-devices. For instance, device 900 may be implemented using one or more personal computers (PCs), servers, mobile devices (e.g., smartphones), tablet devices, wearable devices, and/or any other appropriate devices. The various devices may work alone (e.g., device 900 may be implemented as a single smartphone) or in conjunction (e.g., some components of the device 900 may be provided by a mobile device while other components are provided by a server).

As shown, device 900 may include at least one communication bus 910, one or more processors 920, memory 930, input components 940, output components 950, and one or more communication interfaces 960.

Bus 910 may include various communication pathways that allow communication among the components of device 900. Processor 920 may include a processor, microprocessor, microcontroller, DSP, logic circuitry, and/or other appropriate processing components that may be able to interpret and execute instructions and/or otherwise manipulate data. Memory 930 may include dynamic and/or non-volatile memory structures and/or devices that may store data and/or instructions for use by other components of device 900. Such a memory device 930 may include space within a single physical memory device or spread across multiple physical memory devices.

Input components 940 may include elements that allow a user to communicate information to the computer system and/or manipulate various operations of the system. The input components may include keyboards, cursor control devices, audio input devices and/or video input devices, touchscreens, motion sensors, etc. Output components 950 may include displays, touchscreens, audio elements such as speakers, indicators such as light-emitting diodes (LEDs), printers, haptic or other sensory elements, etc. Some or all of the input and/or output components may be wirelessly or optically connected to the device 900.

Device 900 may include one or more communication interfaces 960 that are able to connect to one or more networks 970 or other communication pathways. For example, device 900 may be coupled to a web server on the Internet such that a web browser executing on device 900 may interact with the web server as a user interacts with an interface that operates in the web browser. Device 900 may be able to access one or more remote storages 980 and one or more external components 990 through the communication interface 960 and network 970. The communication interface(s) 960 may include one or more application programming interfaces (APIs) that may allow the device 900 to access remote systems and/or storages and also may allow remote systems and/or storages to access device 900 (or elements thereof).

It should be recognized by one of ordinary skill in the art that any or all of the components of computer system 900 may be used in conjunction with some embodiments. Moreover, one of ordinary skill in the art will appreciate that many other system configurations may also be used in conjunction with some embodiments or components of some embodiments.

In addition, while the examples shown may illustrate many individual modules as separate elements, one of ordinary skill in the art would recognize that these modules may be combined into a single functional block or element. One of ordinary skill in the art would also recognize that a single module may be divided into multiple modules.

Device 900 may perform various operations in response to processor 920 executing software instructions stored in a computer-readable medium, such as memory 930. Such operations may include manipulations of the output components 950 (e.g., display of information, haptic feedback, audio outputs, etc.), communication interface 960 (e.g., establishing a communication channel with another device or component, sending and/or receiving sets of messages, etc.), and/or other components of device 900.

The software instructions may be read into memory 930 from another computer-readable medium or from another device. The software instructions stored in memory 930 may cause processor 920 to perform processes described herein. Alternatively, hardwired circuitry and/or dedicated components (e.g., logic circuitry, ASICs, FPGAs, etc.) may be used in place of or in combination with software instructions to implement processes described herein. Thus, implementations described herein are not limited to any specific combination of hardware circuitry and software.

The actual software code or specialized control hardware used to implement an embodiment is not limiting of the embodiment. Thus, the operation and behavior of the embodiment has been described without reference to the specific software code, it being understood that software and control hardware may be implemented based on the description herein.

While certain connections or devices are shown, in practice additional, fewer, or different connections or devices may be used. Furthermore, while various devices and networks are shown separately, in practice the functionality of multiple devices may be provided by a single device or the functionality of one device may be provided by multiple devices. In addition, multiple instantiations of the illustrated networks may be included in a single network, or a particular network may include multiple networks. While some devices are shown as communicating with a network, some such devices may be incorporated, in whole or in part, as a part of the network.

Some implementations are described herein in conjunction with thresholds. To the extent that the term “greater than” (or similar terms) is used herein to describe a relationship of a value to a threshold, it is to be understood that the term “greater than or equal to” (or similar terms) could be similarly contemplated, even if not explicitly stated. Similarly, to the extent that the term “less than” (or similar terms) is used herein to describe a relationship of a value to a threshold, it is to be understood that the term “less than or equal to” (or similar terms) could be similarly contemplated, even if not explicitly stated. Further, the term “satisfying,” when used in relation to a threshold, may refer to “being greater than a threshold,” “being greater than or equal to a threshold,” “being less than a threshold,” “being less than or equal to a threshold,” or other similar terms, depending on the appropriate context.

No element, act, or instruction used in the present application should be construed as critical or essential unless explicitly described as such. An instance of the use of the term “and,” as used herein, does not necessarily preclude the interpretation that the phrase “and/or” was intended in that instance. Similarly, an instance of the use of the term “or,” as used herein, does not necessarily preclude the interpretation that the phrase “and/or” was intended in that instance. Also, as used herein, the article “a” is intended to include one or more items and may be used interchangeably with the phrase “one or more.” Where only one item is intended, the terms “one,” “single,” “only,” or similar language is used. Further, the phrase “based on” is intended to mean “based, at least in part, on” unless explicitly stated otherwise.

The foregoing relates to illustrative details of exemplary embodiments and modifications may be made without departing from the scope of the disclosure. Even though particular combinations of features are recited in the claims and/or disclosed in the specification, these combinations are not intended to limit the possible implementations of the disclosure. In fact, many of these features may be combined in ways not specifically recited in the claims and/or disclosed in the specification. For instance, although each dependent claim listed below may directly depend on only one other claim, the disclosure of the possible implementations includes each dependent claim in combination with every other claim in the claim set.

We claim:

1. A heat exchange structure comprising:
a thermally-conductive material comprising: (i) a heat receiving section configured to be in contact with a heat source so as to receive thermal energy from the heat source, and (ii) a thermal energy spreading section configured to pull thermal energy away from the heat receiving section and distribute it into and/or throughout the entire the heat exchange structure; and
a solid state (SS) Martensitic transformation (MT) phase change material (PCM), in contact with and surrounding the thermally-conductive material, configured to readily undergo a solid-solid martensitic transformation from one crystalline structure to another different crystalline structure during a change in temperature in the normal and/or anticipated operating temperatures of the distributed thermal energy from the heat receiving section.

2. The heat exchange structure of claim 1, wherein the heat receiving section is judiciously sized to generally conform to the outer dimensions of the heat source.

3. The heat exchange structure of claim 1, wherein the thermal energy spreading section comprises a plurality of thermal conductivity pathways.

4. The heat exchange structure of claim 3, wherein the plurality of the thermal conductivity pathways of the thermal energy spreading section comprises dendrites, lattices, or periodic structures which penetrate into and/or permeate through the SS MT PCM.

5. The heat exchange structure of claim 4, wherein the dendrites connect to the heat receiving section and outwardly extend away in various directions.

6. The heat exchange structure of claim 5, wherein individual dendrites gradually narrow to a point as they extend outwardly.

7. The heat exchange structure of claim 5, wherein the extension of the dendrite is straight or wavy.

8. The heat exchange structure of claim 5, wherein the dendrites have a tree or fractal pattern in which additional dendrites continually branch from previous dendrites.

9. The heat exchange structure of claim 5, wherein the dendrites extend in two dimensions.

10. The heat exchange structure of claim 9, wherein the dendrites are the same in cross-section in the other dimension.

11. The heat exchange structure of claim 4, wherein the lattices or periodic structures comprise scaffolds or trusses.

12. The heat exchange structure of claim 11, wherein the periodic scaffolds or trusses are spatially tuned or optimized structures.

13. The heat exchange structure of claim 4, wherein the lattices or periodic structures vary in size along at least one axis.

14. The heat exchange structure of claim 4, wherein the plurality of the thermal conductivity pathways of the thermal energy spreading section extend in two or three dimensions.

15. The heat exchange structure of claim 1, further comprising: a heat source which generates thermal energy.

16. The heat exchange structure of claim 15, wherein the heat source is a chip or integrated circuit.

17. The heat exchange structure of claim 15, wherein the heat source connects to heat receiving section of the thermally-conductive material via a press fit, chemical bond, adhesive, and/or solder.

18. The heat exchange structure of claim 15, wherein the heat source is a passive or active electronic component.

19. The heat exchange structure of claim 18, wherein the passive or active electronic component is a standalone element.

20. The heat exchange structure of claim 18, wherein the passive or active electronic component is a sub-element of a chip or integrated circuit.

21. The heat exchange structure of claim 1, having a plating on one or both of top and bottom surfaces thereof.

22. The heat exchange structure of claim 1, further comprising: a plurality of channels provided in the SS MP PCM for flowing a fluid therethrough.

23. The heat exchange structure of claim 22, wherein the channels are at least ten nm across.

24. The heat exchange structure of claim 22, wherein the fluid comprises air, water, hydrofluorocarbon, alcohol-derived solvent, metal or polymer in liquid state, or super-critical CO₂.

25. The heat exchange structure of claim 1, further comprising: a plurality of solid-to-liquid (SL) PCMs incorporated into the SS MP PCM.

26. The heat exchange structure of claim 25, wherein the SL PCMs are at least one hundred nm across.

27. The heat exchange structure of claim 25, wherein the SL PCMs comprise a low-melting-point metal or alloy, wax, organic material, or salt-hydrate.

28. The heat exchange structure of claim 1, wherein neither of the crystalline structures requires physical deformation to achieve the transformation.

29. The heat exchange structure of claim 1, wherein the thermally-conductive material has a thermal-energy conductivity of two hundred W/mK or more.

30. The heat exchange structure of claim 29, wherein of the thermally-conductive material is electrically conductive.

31. The heat exchange structure of claim 30, wherein the thermally-conductive material comprises a metal or alloy.

32. The heat exchange structure of claim 29, wherein of the thermally-conductive material is electrically insulating.

33. The heat exchange structure of claim 29, wherein of the thermally-conductive material is a semiconductor.

34. The heat exchange structure of claim 1, wherein the percentage of the thermally-conductive material in the heat exchange structure, on a volumetric basis, comprises five to fifty percent.

35. The heat exchange structure of claim 1, wherein the SS MT PCM is selected from the group of materials listed in Table 1.

36. The heat exchange structure of claim 1, wherein the heat exchange structure is a heat pipe, vapor chamber, or other high-effective-conductivity structure.
